(19) United States
(12) Patent Application Publication
(10) Pub. No.: US 2010/0147369 A1
(43) Pub. Date: Jun. 17, 2010

(54) SOLAR CELL HAVING NANODIAMOND QUANTUM WELLS

(76) Inventor: Chien-Min Sung, Tansui (TW)

Correspondence Address: THORPE NORTH & WESTERN, LLP., P.O. Box 1219, SANDY, UT, 84091-1219, US

(21) Appl. No.: 12/619,487

(22) Filed: Nov. 16, 2009

Related U.S. Application Data
(60) Provisional application No. 61/122,239, filed on Dec. 12, 2008.
(60) Provisional application No. 61/138,429, filed on Dec. 17, 2008.

(51) Int. Cl. H01L 31/00; H01L 31/18; H01L 31/042; H01L 29/16

(52) U.S. Cl. 136/255; 438/63; 257/52; 977/755; 257/E31.032; 257/E31.003; 257/E29.083

(57) ABSTRACT

The present invention provides materials, devices, and methods for generation of electricity from solar power. In one aspect, the present invention includes a solar cell, including a first conductor, a doped silicon layer in electrical communication with the first conductor, a nanodiamond layer in contact with the doped silicon layer, a doped amorphous diamond layer in contact with the nanodiamond layer, and a second conductor in electrical communication with the doped amorphous diamond layer.

### PRIORITY DATA

This application claims the benefit of U.S. Provisional Patent Application Ser. No. 61/122,239 filed on Dec. 12, 2008, and of U.S. Provisional Patent Application Ser. No. 61/138,429, filed on Dec. 17, 2008, each of which is incorporated herein by reference.

### FIELD OF THE INVENTION

The present invention relates generally to devices and methods for generating electrical power, including in particular the use of nanodiamond materials. Accordingly, the present application involves the fields of physics, chemistry, electricity, and material science.

### BACKGROUND OF THE INVENTION

Solar cell technology has progressed over the past several decades resulting in a significant contribution to potential power sources in many different applications. Despite dramatic improvements in materials and manufacturing methods, solar cells still have conversion efficiency limits well below theoretical efficiencies, with current conventional solar cells having maximum efficiency of about 26%. Various approaches have attempted to increase efficiencies with some success. Some previous approaches include light trapping structures and buried electrodes in order to minimize surface area shaded by the conductive metal grid. Other methods have included rear contact configurations where recombination of hole-electron pairs occurs along the rear side of the cell.

When used as an electron-emitting material, amorphous diamond materials offer the potential for increasing performance due to the low work function such materials provide. Further, amorphous diamond materials can provide a wide range of band gaps that can allow for “step” excitation of electrons. In particular, electrons may be excited by incident energy, stepping up to higher discrete energy levels much like stepping up a ladder, eventually reaching enough energy that they can be emitted as free electrons. While much success has been obtained using amorphous diamond materials in various generating devices, drawbacks in performance, manufacturability, cost, and other factors have remained.

### SUMMARY OF THE INVENTION

Accordingly, the present invention provides materials, devices, and methods for generation of electricity from solar power. In one aspect, the present invention includes a solar cell, including a first conductor, a doped silicon layer in electrical communication with the first conductor, a nanodiamond layer in contact with the doped silicon layer, a doped amorphous diamond layer in contact with the nanodiamond layer, and a second conductor in electrical communication with the doped amorphous diamond layer.

The various layers of the solar cells of the present invention can be of a variety of thicknesses and configurations depending on the materials used and the intended use of the device. For example, in one aspect the doped amorphous diamond layer has a thickness of less than about 250 nanometers. In another aspect, the nanodiamond layer has a thickness of less than about 150 nanometers. In yet another aspect, the doped silicon layer is a P-type material and the doped amorphous diamond layer is an N-type material. In a further aspect, the second conductor comprises a doped portion of the amorphous diamond layer. In another aspect, at least one of the first conductor and the second conductor is transparent.

The present invention additionally provides methods for making solar cells having improved energy conversion. In one aspect, such and aspect can include forming a doped silicon layer on a substrate, depositing a nanodiamond layer on the silicon layer, and depositing a doped amorphous diamond layer on the nanodiamond layer. In one aspect the silicon layer is an amorphous silicon layer. In another aspect, the silicon layer is N-type doped and the amorphous diamond layer is P-type doped. In yet another aspect, the silicon layer is P-type doped and the amorphous diamond layer is N-type doped. In a further aspect, the silicon layer is a thin-film silicon layer.

Various method for depositing the nanodiamond layer are also contemplated. In one aspect, for example, depositing the nanodiamond layer further includes eletrophoretically depositing nanodiamond particles. In another aspect the depositing the nanodiamond layer further includes sputtering nanodiamond particle from a diamond target.

The present invention additionally provides semiconductor devices. In one aspect, for example, such a semiconductor device can include a first conductor, a first semiconductor layer in electrical communication with the first conductor, a nanodiamond layer in contact with the first semiconductor layer, a second semiconductor layer in contact with the nanodiamond layer, and a second conductor in electrical communication with the second semiconductor layer. In one specific aspect, the first semiconductor layer is silicon and the second semiconductor layer is amorphous diamond. In another aspect, the semiconductor device is a solar cell.

There has thus been outlined, rather broadly, the more important features of the invention so that the detailed description thereof that follows may be better understood, and so that the present contribution to the art may be better appreciated. Other features of the present invention will become clearer from the following detailed description of the invention, taken with the accompanying drawings and claims, or may be learned by the practice of the invention.

### BRIEF DESCRIPTION OF THE DRAWINGS

FIG. 1 shows a side view illustration of a solar cell according to one embodiment of the present invention.

FIG. 2 shows a side view illustration of a solar cell according to another embodiment of the present invention.

FIG. 3(a)-FIG. 3(e) show a series of illustrations of a solar cell being fabricated in accordance with an embodiment of the present invention.

FIG. 4(a)-FIG. 4(e) show a series of illustrations of a solar cell being fabricated in accordance with another embodiment of the present invention.

The drawings will be described further in connection with the following detailed description. Further, these drawings are not necessarily to scale and are by way of illustration only such that dimensions and geometries can vary from those illustrated.

### DETAILED DESCRIPTION

Before the present invention is disclosed and described, it is to be understood that this invention is not limited to the particular structures, process steps, or materials disclosed herein, but is extended to equivalents thereof as would be recognized by those ordinarily skilled in the relevant arts. It should also be understood that terminology employed herein is used for the purpose of describing particular embodiments only and is not intended to be limiting.

It must be noted that, as used in this specification and the appended claims, the singular forms “a,” “an,” and “the” include plural referents unless the context clearly dictates otherwise. Thus, for example, reference to “a layer” includes one or more of such layers, and reference to “the dopant” includes reference to one or more of such dopants.

Definitions

In describing and claiming the present invention, the following terminology will be used in accordance with the definitions set forth below.

As used herein, “diamond” refers to a crystalline structure of carbon atoms bonded to other carbon atoms in a lattice of tetrahedral coordination known as sp³ bonding. Specifically, each carbon atom is surrounded by and bonded to four other carbon atoms, each located on the tip of a regular tetrahedron. Further, the bond length between any two carbon atoms is 1.54 angstroms at ambient temperature conditions, and the angle between any two bonds is 109 degrees, 28 minutes, and 16 seconds although experimental results may vary slightly. The structure and nature of diamond, including its physical and electrical properties are well known in the art.

As used herein, “distorted tetrahedral coordination” refers to a tetrahedral bonding configuration of carbon atoms that is irregular, or has deviated from the normal tetrahedron configuration of diamond as described above. Such distortion generally results in lengthening of some bonds and shortening of others, as well as the variation of the bond angles between the bonds. Additionally, the distortion of the tetrahedron alters the characteristics and properties of the carbon to effectively lie between the characteristics of carbon bonded in sp³ configuration (i.e., diamond) and carbon bonded in sp² configuration (i.e., graphite). One example of material having carbon atoms bonded in distorted tetrahedral bonding is amorphous diamond.

As used herein, “diamond-like carbon” refers to a carbonaceous material having carbon atoms as the majority element, with a substantial amount of such carbon atoms bonded in distorted tetrahedral coordination. Diamond-like carbon can be formed, for example by a vapor deposition process. A variety of other elements can be included in the diamond-like carbon material as either impurities, or as dopants, including without limitation, hydrogen, nitrogen, silicon, metals, etc.

As used herein, “amorphous diamond” refers to a type of diamond-like carbon having carbon atoms as the majority element, with a substantial amount of such carbon atoms bonded in distorted tetrahedral coordination. In one aspect, the amount of carbon in the amorphous diamond can be at least about 90%, with at least about 20% of such carbon being bonded in distorted tetrahedral coordination. Amorphous diamond also has a higher atomic density than that of diamond (176 atoms/cm³). Further, amorphous diamond and diamond materials contract upon melting.

As used herein, “nanodiamond” refers to diamond particle produced from synthetic or natural diamond sources, where such nanodiamond particles have a size that is in the nanodiamond range. In one aspect, nanodiamonds can have a size of less than or equal to about 500 nanometers. In another aspect, nanodiamonds can have a size of less than or equal to about 100 nanometers. In yet another aspect, nanodiamonds can have a size of less than or equal to about 50 nanometers. In a further aspect, nanodiamonds can have a size of less than or equal to about 10 nanometers.

As used herein, “work function” refers to the amount of energy, typically expressed in eV, required to cause electrons in the highest energy state of a material to emit from the material info a vacuum space. Thus, a material such as copper having a work function of about 4.5 eV would require 4.5 eV of energy in order for electrons to be released from the surface into a theoretical perfect vacuum at 0 eV.

As used herein, “electron affinity” refers to the tendency of an atom to attract or bind a free electron into one of its orbitals. Further, “negative electron affinity” (NEA) refers to the tendency of an atom to either repulse free electrons, or to allow the release of electrons from its orbitals using a small energy input. NEA is generally the energy difference between a vacuum and the lowest energy state within the conduction band. It will be recognized that negative electron affinity may be imparted by the compositional nature of the material, or the crystal irregularities, e.g. defects, inclusions, grain boundaries, twin planes, or a combination thereof.

As used herein, “nanotube” refers to a cylindrical molecular structure having a length to width ratio in excess of about 1,000. In particular, carbon nanotubes are formed of rolled hexagonal graphite molecules attached at the edges. Carbon nanotubes may have dimensions of about 1 nanometer to about 10 nanometer in cross section and lengths of about 1 micrometer to about 1 millimeter. Carbon nanotubes may have single wall, double wall, or other configurations.

As used herein, “in electrical communication” refers to a relationship between materials that allows electrical current to flow at least partially between them. This definition is intended to include aspects where the structures are in physical contact and those aspects where the structures are not in physical contact. Two materials which are in electrical communication may form an Ohmic contact (providing a substantially linear current versus voltage characteristic symmetric about zero) or a Schottky contact (where an electrical potential exists between the two materials and a non-linear current versus voltage characteristic results). For example, two plates physically connected together by a resistor are in electrical communication, and thus allow electrical current to flow between them. Conversely, two plates separated by a dielectric material are not in physical contact, but, when connected to an alternating current source, allow electrical current to flow between them by capacitive means. Moreover, depending on the insulative nature of the dielectric material, electrons may be allowed to bore through, or jump across the dielectric material when enough energy is applied.

As used herein, “conversion efficiency” refers to a ratio of output power delivered to an electrical load by the solar cell or other structure compared to the input power or incident radiation. Conversion efficiency is typically measured according to standard test conditions corresponding to a given solar irradiance according to the “air mass 1.5 spectrum” as is known in the art.

As used herein, “metal” refers to a metal, or an alloy of two or more metals. A wide variety of metallic materials are known, such as aluminum, copper, chromium, silver, gold, iron, steel, stainless steel, titanium, tungsten, zinc, zirconium, molybdenum, etc., including alloys and compounds thereof.

As used herein, the term “substantially” refers to the complete or nearly complete extent or degree of an action, characteristic, property, state, structure, item, or result. For example, an object that is “substantially” enclosed would mean that the object is either completely enclosed or nearly completely enclosed. The exact allowable degree of deviation from absolute completeness may in some cases depend on the specific context. However, generally speaking the nearness of completion will be so as to have the same overall result as if absolute and total completion were obtained. The use of “substantially” is equally applicable when used in a negative connotation to refer to the complete or near complete lack of an action, characteristic, property, state, structure, item, or result. For example, a composition that is “substantially free of” particles would either completely lack particles, or so nearly completely lack particles that the effect would be the same as if it completely lacked particles. In other words, a composition that is “substantially free of” an ingredient or element may still actually contain such item as long as there is no measurable effect thereof.

As used herein, the term “about” is used to provide flexibility to a numerical range endpoint by providing that a given value may be “a little above” or “a little below” the endpoint.

As used herein, a plurality of items, structural elements, compositional elements, and/or materials may be presented in a common list for convenience. However, these lists should be construed as though each member of the list is individually identified as a separate and unique member. Thus, no individual member of such list should be construed as a de facto equivalent of any other member of the same list solely based on their presentation in a common group without indications to the contrary.

Concentrations, amounts, and other numerical data may be expressed or presented herein in a range format. It is to be understood that such a range format is used merely for convenience and brevity and thus should be interpreted flexibly to include not only the numerical values explicitly recited as the limits of the range, but also to include all the individual numerical values or sub-ranges encompassed within that range as if each numerical value and sub-range is explicitly recited. As an illustration, a numerical range of “about 1 micrometers to about 5 micrometers” should be interpreted to include not only the explicitly recited values of about 1 micrometer to about 5 micrometers, but also include individual values and sub-ranges within the indicated range. Thus, included in this numerical range are individual values such as 2, 3, and 4 and sub-ranges such as from 1-3, from 2-4, and from 3-5, etc.

This same principle applies to ranges reciting only one numerical value. Furthermore, such an interpretation should apply regardless of the breadth of the range or the characteristics being described.

The Invention

The present invention involves semiconductor devices such as solar cells having improved energy conversion. It should be noted that, although the following discussion is centered on solar cells, the scope of the present invention should not be limited to such, as a variety of semiconductor devices can benefit from the teachings described herein.

It is presently believed that a significant source of efficiency loss in solar cells using an amorphous diamond layer as an electron emitter is back conversion of excited electrons into heat. In particular, while the many closely-spaced energy bands can facilitate the stepping up of electron energy as heat or incident radiation is received by the amorphous diamond layer, these closely-spaced energy bands can also facilitate the back conversion of electron energy into heat (e.g., phonons or lattice vibrations). Accordingly, improved efficiency can be obtained by using a thin (e.g., 250 nanometer or less) energy receiving portion within the amorphous diamond layer and positioning a conductive material in electrical communication with the energy receiving portion of the amorphous diamond layer. Energy received by the amorphous diamond excites free electrons, which are efficiently moved into the conductive material, since only a short distance needs to be traveled. For example, conversion efficiency in excess of about 20% is believed to be possible using embodiments of the present invention.

It has now been discovered that depositing a nanodiamond layer between the N-type and P-type materials of a solar cell can increase both the output voltage and the electrical current, thereby increasing the conversion efficiency of the device. Nanodiamond layers as formed according to aspects of the present invention have wide band gaps, and thus compliment wide band gap materials used as semiconductor layers, such as doped amorphous diamond. For example, depositing a nanodiamond layer between a P-type silicon layer and an N-type amorphous diamond layer increases the band gap relative to both semiconductor layers.

Furthermore, the nanodiamond layers of the present invention are particularly useful in the construction of thin film solar cells, for example, those utilizing thin film amorphous diamond layers. One limitation in the efficiency of solar cells is back conversion of energy from excited charge carriers (e.g., electrons) into heat before the charge carrier can reach an anode or cathode conductor where useful electrical energy can be extracted. Use of a thin amorphous diamond layer may increase the ability of excited electrons to reach a conductor before losing energy. In particular, an amorphous diamond layer can include a relatively thin energy receiving portion, for example having a thickness of about 250 nanometers or less, or as a more particular example, having a thickness of about 100 nanometers or less. A conductive material is positioned in electrical communication with the energy receiving portion of the amorphous diamond layer. The use of a thin amorphous diamond layer allows for free electrons generated in the amorphous diamond layer to quickly reach the conductive material, enhancing the conversion efficiency of the solar cell.

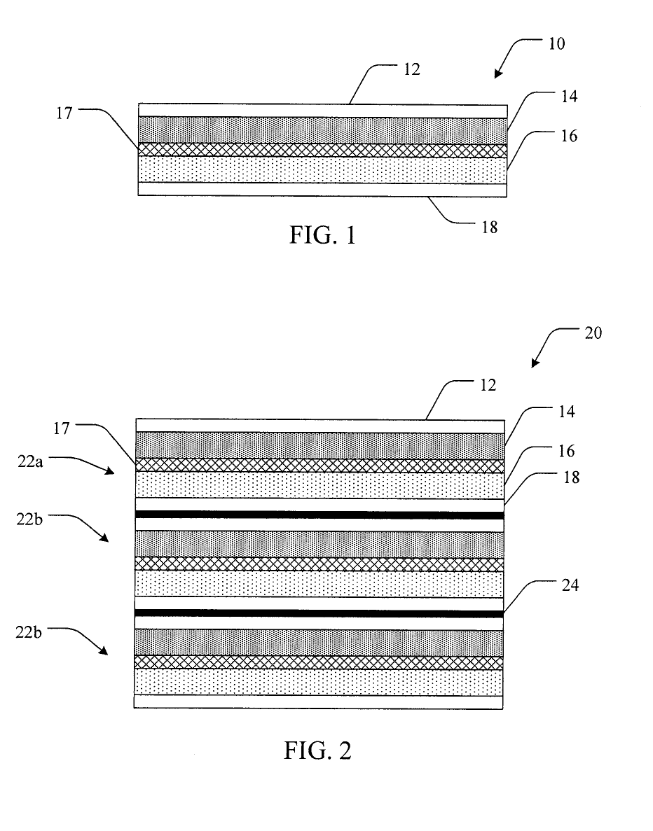

For example, FIG. 1 shows a side view of one embodiment of a solar cell in accordance with an aspect of the present invention. Specifically, the solar cell, shown generally at 10, includes a first conductor 12. A doped silicon layer 14 is in electrical communication with the first conductor. The silicon layer may be, for example, amorphous or microcrystalline, and it may also be thick or thin film. A nanodiamond layer 17 is in contact with the silicon layer 14. A doped amorphous diamond layer 16 is in contact with the nanodiamond layer 17. The amorphous diamond layer has a thickness of less than about 250 nanometers, or as a more particular example, a thickness of less than about 100 nanometers. A second conductor 18 is in electrical communication with the doped amorphous diamond layer. In one aspect, the silicon layer, the nanodiamond layer, and the amorphous diamond layer form a PIN junction.

Various dopants are contemplated for inclusion in the semiconductor devices of the present invention. For example, silicon may be doped with boron to provide a P-type material and amorphous diamond may be doped with nitrogen to provide an N-type material. As another example, the silicon may be doped with phosphorous to provide an N-type material, and the amorphous diamond may be doped with boron to provide a P-type material. Of course, many other dopants and combinations of dopants may be used to produce P-type and N-type materials as will occur to one of ordinary skill in the art.

The contact between the doped amorphous diamond layer 16, the nanodiamond layer 17, and the doped silicon layer 14 creates a PIN depletion region in which a bias field exists. Incident radiation can create charge carriers within the depletion region, which are swept to the first and second conductor by the bias field present in the depletion region. By keeping the thickness of the amorphous diamond layer relatively small, the distance that free electrons must travel within the amorphous diamond is kept small relative to the carrier diffusion length so that back conversion into heat is reduced. Accordingly, use of a thin amorphous diamond layer helps to increase the percentage of free electrons which can reach the second conductor before stepping down in energy level. Additionally, the nanodiamond layer is essentially a layer of quantum dots. In addition to boosting voltage, the quantum dots can allow ejection of multiple electrons from a single photon interaction. In configurations lacking the nanodiamond layer, one photon often can only generate at most one electron. Excess energy, such as high frequency UV energy, often becomes heat. Nanodiamond can trap photons to form plasmons that can generate multiple electrons, thus boosting both output current and voltage.

Various materials can be used in constructing the solar cell. For example, the first conductor, second conductor, or both, may be formed of a transparent conductor, including for example, indium tin oxide.

If desired, the first conductor, second conductor, or both can be a doped amorphous diamond layer. Amorphous diamond can be doped to increase electrical conductivity while retaining transparency. Doping type and concentration, hydrogen content, sp² and sp³ bonded carbon content, and combinations thereof, can be varied to provide a desired electrical conductivity and light transmissivity. For example, in one aspect, the conductive amorphous diamond can provide an electrical resistance between about 10⁻² and about 10⁻⁵ ohm-cm. In another aspect, the conductive amorphous diamond can provide visible light transmissivity of about 30% to about 90%.

Dopants can include, but are not limited to, metals. As a particular example, the doping can include lithium or a combination of lithium and nitrogen. Various sizes and concentration of metal can be used as a dopant. For example, the doping concentration may be between 1 atom % and 70 atom % of metal, although other ranges such as from about 5 to about 60, from about 10 to about 50, from about 25 to about 40, from about 10 to about 30, from about 1 to about 15, and from about 30 to about 40 atom % may be used according to various aspects of the present invention. Metal may be particulate, having any suitable size, for example, about 1 nanometer to about 1 micrometer, although other ranges such as from about 1 nanometer to about 250 nanometer, from about 5 nanometer to about 50 nanometers, and from about 1 nanometer to about 75 nanometer may be used according to various aspects of the present invention. As a particular example, the doping can include gold particulates.

The solar cell can be constructed on a substrate, as described in further detail below. For example, substrates may include glass, semiconductor, ceramic, and polymer materials. Glass can provide an economical substrate. Polymer materials can also be economical and provide the advantage of a flexible substrate allowing the solar cell to be mounted on a curved surface (e.g., a car rooftop).

It will be appreciated that light or other incident radiation will tend to penetrate the relatively thin layers of the solar cell, and only a portion of the incident radiation will be converted into charge carriers. Accordingly, a plurality of PIN junctions may be stacked on one another to increase the overall efficiency of a solar cell. For example, as shown in FIG. 2, a solar cell 20 can include a plurality of PIN junctions 22a, 22b, and 22c, with each PIN junction having a first conductor 12, a doped thin-film silicon layer 14, a nanodiamond layer 17, a doped amorphous diamond layer 16, and a second conductor 18. The individual PIN junctions may be separated by insulating material 24. Electrical interconnections (not shown) can be provided between the PIN junctions to provide for connection in parallel, series, or combinations thereof, to provide desired current/voltage output characteristics. Additionally, in such stacked configurations, it may be beneficial for the first and second conductors to be transparent, thus allowing light passing there through to more effectively transmitted to the following solar cell in the stack.

While the materials used in each PIN junction can be substantially similar, this results in similar band gaps for each PIN junction. Even higher efficiency may be obtained if the band gaps are varied for some of the PIN junctions. For example, the doping of the silicon, amorphous diamond, or both, can be varied to control the band gap. Wider band gaps can be created in layers closer to the side on which the radiation enters and narrower band gap materials placed deeper within the solar cell. This can further help to improve the efficiency of the solar cell, as the varying band gaps cover a wider range of radiation spectrum. The amorphous diamond itself provides a range of varying band gaps within each layer that helps to capture a broad range of spectral energy.

As another example, carbon nanotubes can be used for one of conductors. The carbon nanotubes can provide high conductivity while remaining substantially transparent to incident radiation, particularly in the longer wavelength infrared regions. A solar cell can include a first conductor that comprises a carbon nanotube layer. The carbon nanotubes can present a non-planar surface to which an N-type doped amorphous diamond layer and a P-type doped thin-film silicon layer conform. This forms a non-planar junction between the P-type and N-type materials. Such a non-planar junction helps to increase the amount of junction area present within a given amount of substrate area, while keeping the distance from the junction to the conductors relatively short. A similar device can be constructed by using N-type doping of the thin-film silicon layer and P-type doping of the amorphous diamond layer.

The carbon nanotubes may be arranged in a mat, in which the carbon nanotubes are randomly disposed. Alternately, the carbon nanotubes may be oriented preferentially, with ends of the carbon nanotubes disposed in a direction substantially perpendicular to a junction. Additionally, in some aspects the carbon nanotubes may be disposed on a conductive substrate (e.g., metal) or an insulating substrate (e.g., glass) that has been coated with a conductor (e.g., indium tin oxide).

Additional enhancement in the operation of the solar cell may be provided by including conductive particulates or carbon nanotubes within the active layers (i.e., within the doped amorphous diamond layer, within the doped silicon layer, or within both) to help reduce the contact resistance between the active layers and the first and/or second conductors.

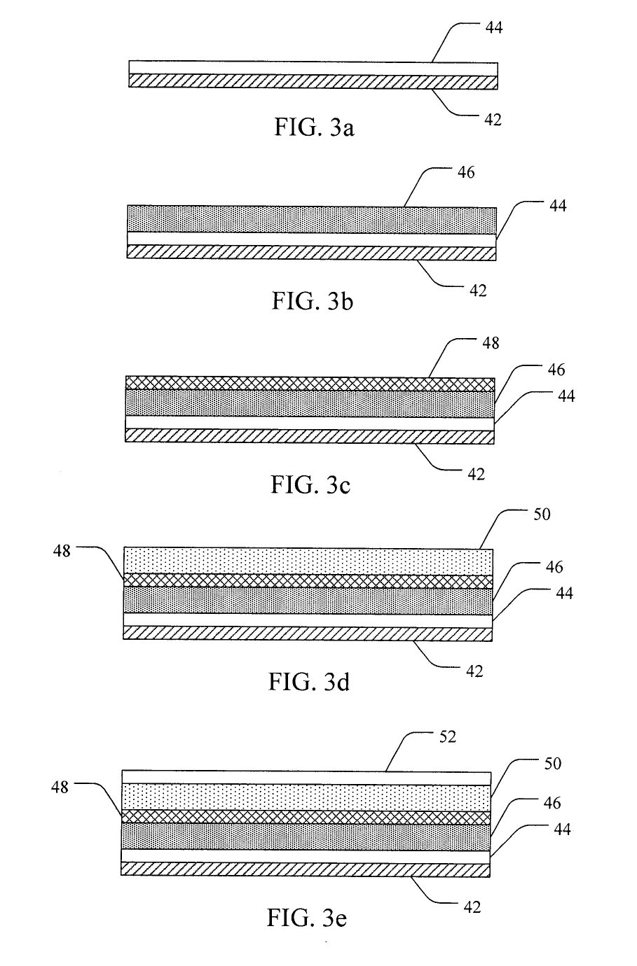

Various techniques of fabricating solar cells in accordance with embodiments of the present invention are possible. For example, FIG. 3(a) through FIG. 3(e) illustrates a solar cell in various stages of fabrication. In one aspect, fabrication can be performed on a substrate that can be temporary for fabrication or a permanent part of the finished device. In some aspects the substrate can be conductive, in which case such a conductive substrate can function as a conductor, such as the first conductor. In an alternative aspect, a separate first conductor 44 can be formed on a separate substrate 42, as is shown in FIG. 3a. Alternatively, the first conductor can be formed on a silicon semiconductor wafer (not shown). The first conductor 44 can be formed by printing, deposition, or otherwise applying a conductive material to the substrate 42. For example, deposition can performed using a process that grows, coats, or otherwise transfers a material onto the substrate. For example, depositing materials can be performed by spin coating, physical vapor deposition (PVD), chemical vapor deposition (CVD), electrochemical deposition (ECD), molecular beam epitaxy (MBE), atomic layer deposition (ALD), and similar processes. A wide variety of variations of vapor deposition methods can be used. Examples of vapor deposition methods include hot filament CVD, radio frequency (RF) CVD, laser CVD (LCVD), metal-organic CVD (MOCVD), sputtering, thermal evaporation PVD, ionized metal PVD (IMPVD), electron beam PVD (EBPVD), reactive PVD, atomic layer deposition (ALD) and the like.

As shown in FIG. 3(b), a silicon layer 46 can be formed on the first conductor 44 (or on the substrate 42 if conductive). The silicon layer can be formed by deposition as described above. As has also been described, the silicon layer can be doped. Doping can be performed while the silicon layer is formed by co-deposition of dopants, for example by co-evaporation of desired dopants while depositing the silicon layer. As another example, doping can be performed after the silicon layer is formed by ion implantation, drive-in diffusion, field-effect doping, electrochemical doping, vapor deposition, or the like. Various dopants can be used to form a P-type material, including for example, boron or an N-type material, including for example, phosphorous, and other dopants as known to those of ordinary skill in the art.

As is shown in FIG. 3(c), a nanodiamond layer 48 can be formed on the silicon layer 46. The nanodiamond layer can be formed by various methods. For example, in one aspect the nanodiamond particles can be formed from an explosive technique such as TNT/RDX, as is known in the art. These nanodiamond particle can then be formed into a nanodiamond layer on the silicon layer via electrophoretic suspension or spin coating techniques. In another aspect, a nanodiamond layer can be sputtered using a PVD process from a diamond target. The diamond target can include materials such as diamond films, synthetic diamond particles, natural diamond particles, etc. Such sputtered nanodiamond layers often have greater sp3 bond proportions than other types of formed nanodiamond layers.

As shown in FIG. 3(d), an amorphous diamond layer 50 can be deposited on the nanodiamond layer 48. The amorphous diamond layer can have a thickness of about 250 nanometers or less, or as a more particular example, a thickness of about 100 nanometers or less. The amorphous diamond layer can be deposited using various techniques, including for example, vapor deposition and other processes. As a particular example, the amorphous diamond layer 50 may be deposited using a cathodic arc method. Cathodic arc methods generally involve the physical vapor deposition of carbon atoms onto a target. An arc is generated by passing a large current through a graphite electrode which vaporizes. A negative bias of varying intensity is used to drive the carbon atoms toward the target. If the carbon atoms contain a sufficient amount of energy (e.g., about 100 eV) they impinge on the target and adhere to its surface to form a carbonaceous material, such as amorphous diamond.

In general, the kinetic energy of the impinging carbon atoms can be adjusted by varying the negative bias applied to the target and the deposition rate can be controlled by the current through the arc. Control of these parameters, as well as others, can also affect the degree of distortion of the carbon atom tetrahedral coordination and the geometry or configuration or the amorphous diamond material. For example, increasing the negative bias can increase sp³ bonding. By measuring the Raman spectra of the material the sp³/sp² ratio can be determined, although it will be appreciated that the distorted tetrahedral portions of an amorphous diamond layer may be neither sp³ nor sp² but a range of bonds which are of intermediate character. Further, increasing the arc current can increase the rate of target bombardment with high flux carbon ions. As a result, temperature can rise so that deposited carbon will convert to more stable graphite. Thus, final configuration and composition (i.e., band gaps, negative electron affinity, and emission surface geometry) of the amorphous diamond material can be controlled by manipulating the cathodic arc conditions under which the material is formed.

The amorphous diamond layer can be doped, for example, by co-deposition of dopants or by ion implantation after deposition, for example, as described above. Various dopants can be used to form an N-type material, including for example, nitrogen, lithium, or combinations thereof, or the form a P-type material, including for example, boron.

As is shown in FIG. 3(e), a second conductor 52 can be formed on the doped amorphous diamond layer 50. The second conductor can be formed by printing, deposition, or otherwise applying a conductive material to the substrate using techniques as described above for deposition of the first conductor. Various conductive materials can be used, including for example a transparent conductor such as indium tin oxide. As another example, the second conductor can be formed by doping an upper portion of the amorphous diamond layer 50 to provide high conductivity (not shown). For example, as discussed above, the diamond-like carbon material may be doped sufficiently to lower the electrical resistance to less than 10⁻² ohm-cm. As yet another example, forming the second conductor can include depositing or growing carbon nanotubes. For example, carbon nanotubes may be formed using various techniques known in the art, and deposited to onto the solar cell to form the second conductor. As another example, carbon nanotubes may be grown in situ using various techniques known in the art.

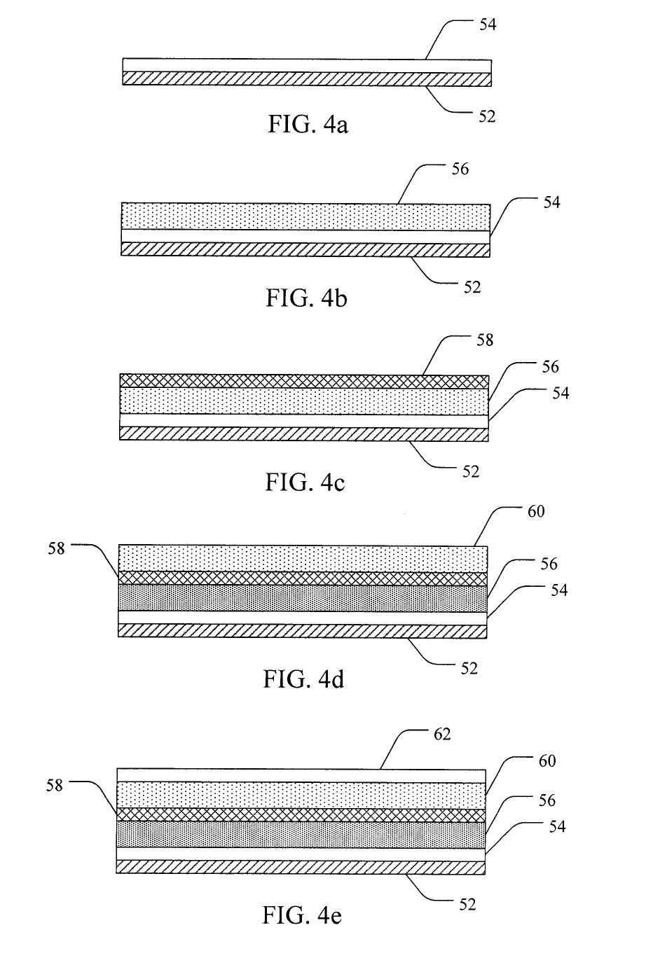

An alternate approach for fabricating a solar cell is illustrated in FIG. 4(a) through FIG. 5(e). The solar cell can be fabricated on a provided substrate 52 as shown in FIG. 4(a). Various substrates, as described above, can be used. A first conductor 54, can be formed on the substrate, for example, using techniques as described above. As with the example techniques described above, a conductive substrate can be utilized, or a portion of the substrate can be rendered conductive. A layer of amorphous diamond 56 is deposited over the first conductor as shown in FIG. 4(b). The amorphous diamond layer can have a thickness of less than about 250 nanometers. The amorphous diamond layer can be doped, for example, using techniques as described above.

As is shown in FIG. 4(c), a nanodiamond layer 58 can be formed on the amorphous diamond layer 56. As has been described, the nanodiamond layer can be formed by various methods. For example, in one aspect the nanodiamond particles can be formed from an explosive technique such as TNT/RDX, as is known in the art. These nanodiamond particle can then be formed into a nanodiamond layer on the silicon layer via electrophoretic suspension techniques. In another aspect, a nanodiamond layer can be sputtered using a PVD process from a diamond target. The diamond target can include materials such as diamond films, synthetic diamond particles, natural diamond particles, etc. Such sputtered nanodiamond layers often have greater sp3 bond proportions than other types of formed nanodiamond layers.

A silicon layer 60 can be deposited on the nanodiamond layer 58 as shown in FIG. 4(d), for example, using techniques as described above. The silicon layer can be doped, in some aspects, using techniques as described above. A second conductor 62 can be formed on top of the silicon layer 60 as shown in FIG. 4(e).

First and second conductors can be deposited as continuous layers (e.g., when using a transparent conductor) or can be patterned to minimize blockage of radiation (e.g., when using silver, gold, or other less transparent conductors). Patterning can be performed using lithography. In lithography, a resist layer is applied to the device being fabricated and is then exposed through a mask to define the various features. Either the exposed (positive photoresist) or unexposed (negative photoresist) regions are washed away by a developer solution to expose portions of the device. Etching or other processing can be used to remove material from the exposed regions. Etching can be performed, for example, by wet etching or dry etching, such as reactive ion etch (RIE).

Alternately, lithography can be performed using a lift off process, where materials are deposited over the developed mask, and then the mask is removed, causing material in masked portions to be removed along with the mask. Liftoff can be advantageous when deposited materials are difficult to etch or otherwise remove. Multiple layers of materials may be deposited and lifted off in a single step.

### EXAMPLES

The following examples illustrate various techniques of making a semiconductor device such as a solar cell according to aspects of the present invention. However, it is to be understood that the following are only exemplary or illustrative of the application of the principles of the present invention. Numerous modifications and alternative compositions, methods, and systems can be devised by those skilled in the art without departing from the spirit and scope of the present invention. The appended claims are intended to cover such modifications and arrangements. Thus, while the present invention has been described above with particularity, the following Examples provide further detail in connection with several specific embodiments of the invention.

### Example 1

A semiconductor device is constructed as follows:

Nanodiamond is produced by detonation of dynamite (TNT+RDX) in an oxygen deficiency container, resulting in nanodiamond particles having a size range of 4-10 nm. The purified nanodiamond is dispersed in an organic binder and dried to form a layer. The layer of nanodiamond is then used as a target for magnetron sputtering with argon ions.

A P type silicon wafer is used as substrate that is bombarded by the sputtered diamond to form clusters of atoms. The coated P type silicon wafer is then overcoated with N type silicon to form a PIN junction suitable for use as a solar cell.

### Example 2

A semiconductor device as in Example 1, except the P type semiconductor is CIGS and the N type semiconductor is CdS.

### Example 3

A semiconductor device as in Example 1, except the P type semiconductor is boron doped amorphous diamond and the N type semiconductor is nitrogen doped amorphous diamond.

### Example 4

A semiconductor device as in Example 2, where electrodes associated with the P and N type materials are made of flexible stainless steel so resulting devices, such as solar panels, are flexible.

Of course, it is to be understood that the above-described arrangements are only illustrative of the application of the principles of the present invention. Numerous modifications and alternative arrangements may be devised by those skilled in the art without departing from the spirit and scope of the present invention and the appended claims are intended to cover such modifications and arrangements. Thus, while the present invention has been described above with particularity and detail in connection with what is presently deemed to be the most practical and preferred embodiments of the invention, it will be apparent to those of ordinary skill in the art that numerous modifications, including, but not limited to, variations in size, materials, shape, form, function and manner of operation, assembly and use may be made without departing from the principles and concepts set forth herein.

What is claimed is:

1. A solar cell, comprising:
a first conductor;
a doped silicon layer in electrical communication with the first conductor;
a nanodiamond interlayer in contact with the doped silicon layer;
a doped amorphous diamond layer in contact with the nanodiamond interlayer; and
a second conductor in electrical communication with the doped amorphous diamond layer.

2. The solar cell of claim 1, wherein the doped amorphous diamond layer has a thickness of less than about 250 nanometers.

3. The solar cell of claim 1, wherein the nanodiamond interlayer has a thickness of less than about 150 nanometers.

4. The solar cell of claim 1, wherein the doped silicon layer is a P-type material and the doped amorphous diamond layer is an N-type material.

5. The solar cell of claim 1, further comprising a substrate disposed under either of the first conductor or the second conductor.

6. The solar cell of claim 5, wherein the substrate is pliable to enable the solar cell to be affixed to a curved surface.

7. The solar cell of claim 1, wherein the second conductor comprises a doped portion of the amorphous diamond layer.

8. The solar cell of claim 1, wherein at least one of the first conductor and the second conductor is transparent.

9. A method of making a solar cell having improved energy conversion, comprising:
forming a doped silicon layer on a substrate;
depositing a nanodiamond interlayer on the silicon layer; and
depositing a doped amorphous diamond layer on the nanodiamond interlayer.

10. The method of claim 9, wherein the silicon layer is an amorphous silicon layer.

11. The method of claim 9, wherein the silicon layer is N-type doped and the amorphous diamond layer is P-type doped.

12. The method of claim 9, wherein the silicon layer is P-type doped and the amorphous diamond layer is N-type doped.

13. The method of claim 9, wherein the silicon layer is a thin-film silicon layer.

14. The method of claim 9, wherein the amorphous diamond layer is less than about 250 nanometers in thickness.

15. The method of claim 9, wherein depositing the nanodiamond layer further includes eletrophoretically depositing nanodiamond particles.

16. The method of claim 9, wherein depositing the nanodiamond layer further includes sputtering nanodiamond particle from a diamond target.

17. A semiconductor device, comprising:
a first conductor;
a first semiconductor layer in electrical communication with the first conductor;
a nanodiamond layer in contact with the first semiconductor layer;
a second semiconductor layer in contact with the nanodiamond layer; and
a second conductor in electrical communication with the second semiconductor layer.

18. The semiconductor device of claim 17, wherein the first semiconductor layer is silicon and the second semiconductor layer is amorphous diamond.

19. The semiconductor device of claim 17, wherein the semiconductor device is a solar cell.
